(19) United States
(12) Patent Application Publication
(10) Pub. No.: US 2025/0355570 A1
(43) Pub. Date: Nov. 20, 2025

(54) MEMORY SYSTEM INCLUDING MEMORY CONTROLLER AND DEVICE, AND OPERATING METHODS THEREOF

(71) Applicant: SK hynix Inc., Gyeonggi-do (KR)

(72) Inventor: Chang Woo LEE, Gyeonggi-do (KR)

(21) Appl. No.: 18/808,089

(22) Filed: Aug. 19, 2024

(30) Foreign Application Priority Data
May 14, 2024 (KR) 10-2024-0062997

(51) Int. Cl. G06F 3/06; G06F 11/10

(52) U.S. Cl. CPC G06F 3/0619; G06F 3/0659; G06F 3/0673; G06F 11/1004

(57) ABSTRACT

An operating method of a memory system includes reading, by a plurality of memory chips, data from a first column of a defective row corresponding to a failure address; generating, by a memory controller, error-corrected data by correcting an error of the read data; and mapping, by a target chip selected from the plurality of memory chips, the failure address to a redundancy address, and writing the error-corrected data to a first column of a redundancy row corresponding to the redundancy address, wherein the reading, the generating, the mapping, and the writing are repeatedly performed on remaining columns of the defective row.

### CROSS-REFERENCE TO RELATED APPLICATION

The present application claims the benefit of Korean Patent Application No. 10-2024-0062997, filed on May 14, 2024, which is incorporated herein by reference in its entirety.

### BACKGROUND

### 1. Field

Various embodiments of the present disclosure relate to semiconductor design technology, and more particularly, to a memory system including a memory device for performing a post-package repair operation.

### 2. Description of the Related Art

Typically, a memory device, such as a dynamic random access memory (DRAM), goes through a test process to detect a defect of the memory device, after it is designed and fabricated.

If there is at least one defect in a great deal of memory cells of a memory device, the memory device cannot perform the desired function properly but is treated as a defective product. However, when there are only a few defective memory cells, it is inefficient in terms of yield to treat the memory device as a defective memory. To address this concern, a method is being utilized which provides redundant memory cells in the memory device in a fabrication stage of the memory device and replaces the defective memory cells of the memory device with the redundant memory cells after the fabrication stage.

A post-package repair operation includes repairing a memory device after a package process. The post-package repair operation may be performed not only in the fabrication process of the memory device, but also in the process when the memory device is used by a user. To perform a post-package repair operation on the memory device while in use, it is preferable to copy the data of a defective memory cell into a redundant memory cell within the memory device.

### SUMMARY

Embodiments of the present disclosure are directed to a memory controller and a memory system capable of performing a row copy operation after error correction during a post-package repair.

According to an embodiment of the present disclosure, an operating method of a memory system includes reading, by a plurality of memory chips, data from a first column of a defective row corresponding to a failure address; generating, by a memory controller, error-corrected data by correcting an error of the read data; and mapping, by a target chip selected from among the plurality of memory chips, the failure address to a redundancy address, and writing the error-corrected data to a first column of a redundancy row corresponding to the redundancy address, wherein the reading, the generating, the mapping, and the writing are repeatedly performed on remaining columns of the defective row.

According to an embodiment of the present disclosure, a memory system includes a plurality of memory chips configured to read data from a defective row corresponding to a failure address; and a memory controller configured to receive the read data from the plurality of memory chips, and generate error-corrected data by correcting an error in the read data, wherein a target chip selected from the plurality of memory chips performs mapping the failure address to a redundancy address, writing the error-corrected data to a redundancy row corresponding to the redundancy address, and releasing the mapping.

According to an embodiment of the present disclosure, an operating method of a memory controller includes providing, to a plurality of memory chips, a read command with a failure address indicating a defective row; generating error-corrected data by correcting an error in data read from the plurality of memory chips; controlling a target chip selected from the plurality of memory chips, to enter an individual chip mode; and instructing, to the target chip, a mapping operation for mapping the defective row of the target chip to a redundancy row, and providing a write command with the error-corrected data, wherein the providing, the generating, the entering, and the instructing of the mapping operation are repeatedly performed on columns of the defective row.

According to an embodiment of the present disclosure, a memory device includes a memory cell region including a plurality of normal rows and a plurality of redundancy rows; a repair control circuit configured to selectively activate a plurality of repair control signals according to a result of comparing an input address with a plurality of failure candidate addresses, and deactivate an activated repair control signal of the plurality of repair control signals according to a mapping release signal; a row control circuit configured to select a row corresponding to the input address or a redundancy address, from the memory region, according to the activated repair control signal; and a data input and output (input/output) circuit configured to provide, to a memory controller, first data read from the memory cell region, and second data provided from the memory controller to the memory cell region when entering an individual chip mode.

Further, according to embodiments of the present disclosure, the memory system may perform a repair operation without data loss during run-time by performing a row copy operation after error correction during a post-package repair. In addition, the memory system may reduce the power consumption and time due to the unnecessary write-back operation by omitting the row copy operation for columns where no error is detected.

### BRIEF DESCRIPTION OF THE DRAWINGS

FIG. 1 is a block diagram illustrating a data processing system according to an embodiment of the present disclosure.

FIG. 2 is a block diagram illustrating a memory system according to an embodiment of the present disclosure.

FIG. 3 is a detailed configuration diagram illustrating a memory chip of FIG. 2.

FIG. 4 is a timing diagram for describing an operation of a mode setting circuit and a repair control circuit of FIG. 3.

FIG. 5 is a diagram for describing an operation of a memory system according to an embodiment of the present disclosure.

FIGS. 6A and 6B are diagrams of operations of FIG. 5.

FIG. 7 is a flowchart describing an operation of a memory controller according to an embodiment of the present disclosure.

FIG. 8 is a flowchart describing an operation of a memory device according to an embodiment of the present disclosure.

FIGS. 9A to 9C are diagrams for describing a row copy operation of a memory system according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

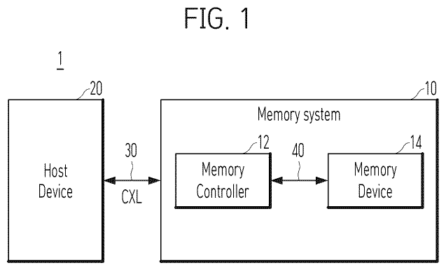

FIG. 1 is a block diagram illustrating a data processing system 1 according to an embodiment of the present disclosure.

Referring to FIG. 1, the data processing system 1 may include a host device 20 and a memory system 10.

The memory system 10 may include a memory controller 12 and a memory device 14. The memory system 10 may store data under the control of the host device 20, such as a cellular phone, a smartphone, an MP3 player, a laptop computer, a desktop computer, a game player, a TV, a tablet PC, or an in-vehicle infotainment system. The host device 20 may be an external device of the memory system 10.

The memory system 10 may be manufactured as any of various types of memory modules depending on a host interface. The host interface is a communication method with the host device 20. The memory system 10 may be configured with any of various types of memory modules, such as a solid state drive (SSD), a multimedia card in a form of an MMC, an eMMC, an RS-MMC, and a micro-MMC, a secure digital card in a form of an SD, a mini-SD, and a micro-SD, a universal serial bus (USB) memory module, a universal flash storage (UFS) device, a personal computer memory card international association (PCMCIA) card type memory module, a peripheral component interconnection (PCI) card type memory module, a PCI express (PCI-e or PCIe) card type memory module, a compact flash (CF) card, a smart media card, and a memory stick.

The memory system 10 may be manufactured in any of various package types. For example, the memory system 10 may be manufactured in any of various package types such as a package on package (POP), a system in package (SIP), a system on chip (SOC), a multi-chip package (MCP), a chip on board (COB), a wafer-level fabricated package (WFP), a wafer-level stack package (WSP), etc.

The memory device 14 may store data. The memory device 14 operates under control of the memory controller 12. The memory device 14 may include a memory cell array including a plurality of memory cells that store data. In an embodiment, the memory cell array may include a plurality of memory blocks. Each memory block may include a plurality of memory cells. One memory block may include a plurality of pages. In an embodiment, the page may be a unit for storing data in the memory device 14 or reading data stored in the memory device 14.

In an embodiment, the memory device 14 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory, a resistive random access memory (RRAM), a phase-change random access memory (PRAM), a magnetoresistive RAM (MRAM), a ferroelectric RAM (FRAM), a spin transfer torque RAM (STT-RAM), or others.

The memory device 14 may receive a command and an address from the memory controller 12 and access an area selected by the address of the memory cell array. That is, the memory device 14 may perform an operation instructed by the command on the area selected by the address. For example, the memory device 14 may perform a write operation (e.g., a program operation) to write data to the area selected by the address. During a read operation, the memory device 14 may read data from the area selected by the address.

The memory controller 12 may control an overall operation of the memory system 10. The memory controller 12 may control the memory device 14 to perform the write operation, the read operation, or other operations according to a request from the host device 20. For example, during the write operation, the memory controller 12 may provide a write command, an address, and data to the memory device 14. During the read operation, the memory controller 12 may provide a read command and an address to the memory device 14.

The host device 20 may communicate with the memory system 10 using a communication interface or standard such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a compute express link (CXL), a universal flash storage (UFS), a secure digital (SD), a multi-media card (MMC), an embedded MMC (eMMC), a dual in-line memory module (DIMM), a registered DIMM (RDIMM), and a load reduced DIMM (LRDIMM).

In an embodiment, the host device 20 may communicate with the memory system 10 through a first interface 30. The first interface 30 may be referred to as a host interface. The first interface 30 may include an interface implemented based on a compute express link (CXL) protocol (i.e., a CXL interface). The CXL protocol may use a serial interface. The CXL interface is an interface based on a PCIe, and may be an interface designed for a Central Processing Unit (CPU), a Graphic Processing Unit (GPU), and various types of accelerators to use memory more efficiently. By connecting the memory system 10 to the host device 20 through the CXL interface, the memory capacity of a computer system such as a data center and a server can be increased, and various processors in the computer system can share the memory device.

The memory controller 12 and the memory device 14 may communicate through a second interface 40. The second interface 40 may be referred to as a memory interface. The second interface 40 may include an interface implemented based on a dual inline memory module (DIMM) protocol.

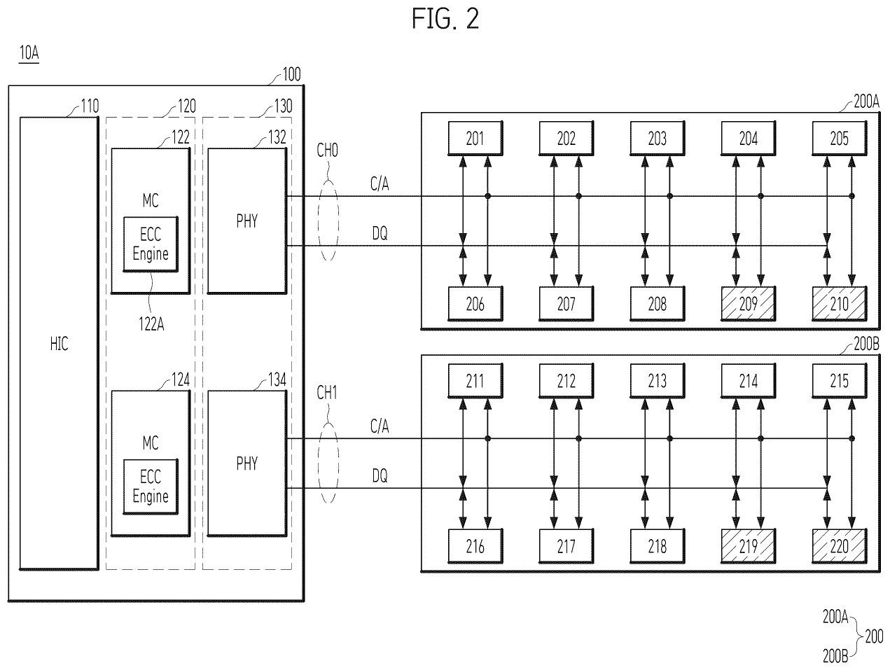

FIG. 2 is a block diagram illustrating a memory system 10A according to a first embodiment of the present disclosure.

Referring to FIG. 2, the memory system 10A may include a memory controller 100 and a memory device 200.

The memory controller 100 may include a host interface circuit (HIC) 110, a module control logic 120, and a memory interface logic 130.

The host interface circuit 110 may communicate with a host (e.g., the host device 20 in FIG. 1) through a host interface. The host interface circuit 110 may communicate with the host through a CXL interface.

The module control logic 120 may be coupled to the memory device 200 through the memory interface logic 130 and control the overall operation of the memory device 200.

The memory interface logic 130 may communicate with the memory device 200 through a memory interface. The memory interface logic 130 may transmit a signal such as a command and an address (hereinafter referred to a command/address signal C/A) to the memory device 200, and transmit and receive data DQ to and from the memory device 200. The memory interface logic 130 may communicate with the memory device 200 through a DIMM interface.

The memory device 200 may include a plurality of memory modules that independently communicate with the memory controller 100 through channels separated from each other. When the memory device 200 includes a plurality of memory modules, the memory interface logic 130 may include a plurality of physical interface circuits PHYs respectively corresponding to the plurality of memory modules, to communicate with a corresponding memory module through a dedicated channel. In addition, the module control logic 120 may include a plurality of module controllers MCs respectively corresponding to the plurality of physical interface circuits PHYs to control a corresponding memory module.

In the illustrated example of FIG. 2, the memory device 200 may include first and second memory modules 200A and 200B, and each of the first and second memory modules 200A and 200B may include 10 memory chips 201-210, 211-220. The module control logic 120 may include first and second module controllers 122 and 124 for controlling the first and second memory modules 200A and 200B, respectively. The memory interface logic 130 may include first and second physical interface circuits 132 and 134 communicating with the first and second memory modules 200A and 200B through first and second channels CH0 and CH1, respectively.

The first physical interface circuit 132 may be coupled to the 10 memory chips 201 to 210 through the first channel CH0. The first physical interface circuit 132 may transmit and receive data to and from the 10 memory chips 201 to 210 through 40 data lines DQ<0:39>. For example, the memory chip 201 may input and output data through four data lines and four data pads, and the memory chip 202 may input and output data through four data lines and four data pads. In this case, the number of bits of data input and output at a time may be determined according to a burst length. For example, when the burst length is set to 16, each of the memory chips 201 to 210 may input and output 8 bytes (i.e., 4*16 bits) of data at a time. Furthermore, the first physical interface circuit 132 may transmit the command/address signal C/A to the memory chips 201 to 210 through control signal lines. The control signal lines may be commonly coupled to the memory chips 201 to 210 so that the command/address signal C/A may be shared by the memory chips 201 to 210.

Each of the memory chips 201 to 210 may include one or more chips (e.g., DRAM chips). For example, a plurality of chips included in the memory chip may be stacked using 3-dimensional stacking (3DS) or wire bonding. However, the embodiments of the present disclosure are not limited thereto, and each of the memory chips 201 to 210 may include different types of chips. For example, at least one of the memory chips 201 to 210 may have a configuration different from that of the other memory chips, and/or may be coupled to the memory controller 100 by using different methods. The form factor of the memory module may have various forms such as an Add-in-Card (AIC) and an Enterprise and Data Center SSD Form Factor (EDSFF).

Some (e.g., 8) memory chips 201 to 208 among the 10 memory chips 201 to 210 may be used to store user data, and the remaining memory chips 209 and 210 (e.g., two) may be used to store an error correction code. Accordingly, 32-bit user data and an 8-bit error correction code per a burst length may be input and output to and from one memory module. For example, when the burst length is set to 16, the memory chips 201 to 208 may input and output 64-byte user data at a time, and the memory chips 209 and 210 may input and output a 16-byte error correction code at a time.

The first module controller 122 may control the first memory module 200A through the first physical interface circuit 132. In particular, the first module controller 122 may include an error correction code (ECC) engine 122A that handles errors in data of the first memory module 200A. During a write operation, the ECC engine 122A may generate a 16-byte error correction code based on 64-byte user data, and provide the generated error correction code to the first memory module 200A. During a read operation, the ECC engine 122A may correct an error of 64-byte user data read from the first memory module 200A by using a 16-byte error correction code read from the first memory module 200A.

The second physical interface circuit 134 may be coupled to 10 memory chips 211 to 220 through the second channel CH1. The second physical interface circuit 134 may have substantially the same configuration as the first physical interface circuit 132.

Each module controller MC of the memory controller 100 may provide, to a corresponding memory module, a repair command for a post-package repair operation along with a failure address detected after being packaged, according to a request from a host. According to the repair command, the memory chips of each memory module may store the failure address in an internal storage circuit and perform an operation of mapping the failure address to an extra redundancy address. In some embodiments, the internal storage circuit may include a volatile or nonvolatile storage circuit, and the post-package repair operation may include at least one of a soft post-package repair operation for storing the failure address in a volatile storage circuit and a hard post-package repair operation for storing the failure address permanently in a nonvolatile storage circuit. During the post-package repair operation, a row copy operation is accompanied in which data of memory cells corresponding to the failure address is copied to memory cells corresponding to the redundancy address.

Hereinafter, a detailed configuration of memory chips according to an embodiment of the present disclosure will be described with reference to the drawings. In the following embodiment, the memory system 10A including the first module controller 122 and the first memory module 200A will be described as an example.

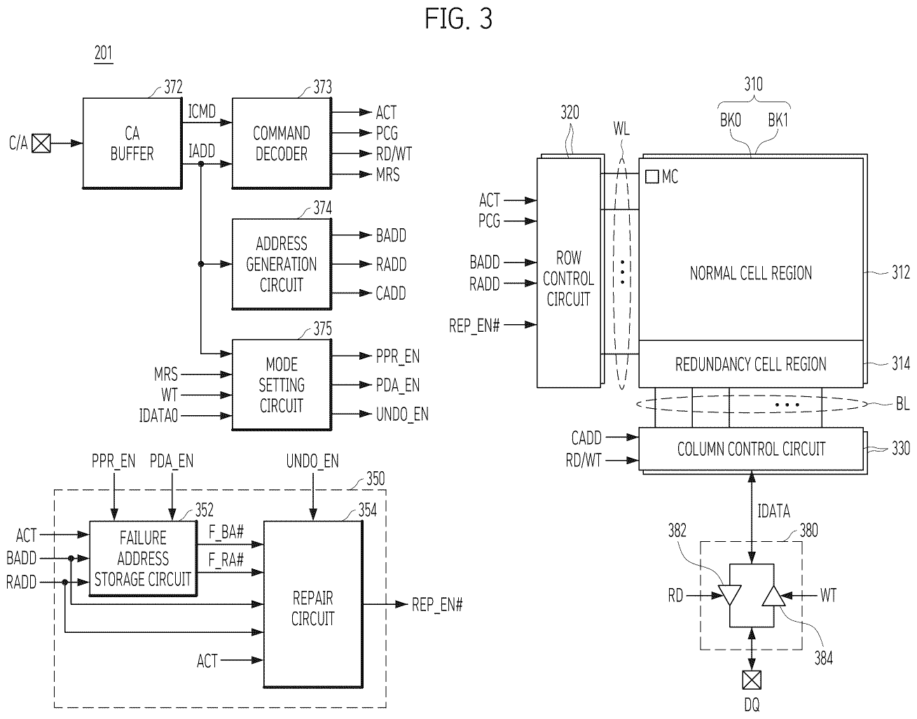

FIG. 3 is a detailed configuration diagram illustrating a memory chip of FIG. 2, e.g., the memory chip 201.

Referring to FIG. 3, the memory chip 201 may include a memory cell region 310, a row control circuit 320, a column control circuit 330, a repair control circuit 350, a command and address (CA) buffer 372, a command decoder 373, an address generation circuit 374, a mode setting circuit 375, and a data input and output (input/output) circuit 380.

The memory cell region 310 may include a plurality of memory cells MC disposed in an array type. The plurality of memory cells MC may be respectively coupled to a plurality of word lines WL and a plurality of bit lines BL. The plurality of word lines WL may extend in a first direction (e.g., a row direction) and may be sequentially disposed in a second direction (e.g., a column direction) perpendicular to the first direction. The plurality of bit lines BL may extend in the column direction and may be sequentially disposed in the row direction. The memory cell region 310 may be divided into a plurality of banks (e.g., a first bank BK0 and a second bank BK1). The number of banks or the number of memory cells MC may be determined according to the capacity of the memory chip. The row control circuit 320 and the column control circuit 330 may be provided in a number corresponding to the number of a plurality of banks.

Each bank of the memory cell region 310 may include a normal cell region 312 in which normal word lines coupled to normal memory cells are disposed, and a redundancy cell region 314 in which redundancy word lines coupled to redundancy memory cells are disposed. When a defective memory cell (i.e., a repair target cell) is found in the normal cell region 312, a repair operation may be performed to replace a defective word line (i.e., a repair target word line) coupled to the defective memory cell with a redundancy word line of the redundancy cell region 314.

The CA buffer 372 may receive a command/address signal C/A from an external device (e.g., the memory controller 100 of FIG. 2). The CA buffer 372 may buffer the command/address signal C/A to output an internal command ICMD and an internal address IADD.

The command decoder 373 may decode the internal command ICMD output from the CA buffer 372 to generate an active command ACT, a precharge command PCG, a read command RD, a write command WT, and a mode setting command MRS.

The address generation circuit 374 may classify the internal address IADD received from the CA buffer 372 as a bank address BADD, a row address RADD and a column address CADD. Depending on an embodiment, the address generation circuit 374 may interpret some bits of the internal address IADD as the bank address BADD and the row address RADD, and interpret the remaining bits as the column address CADD. The address generation circuit 374 may determine the internal address IADD as the bank address BADD and the row address RADD when an active operation is directed as a result of the decoding by the command decoder 373 and determine the internal address IADD as the column address CADD when a read or write operation is directed by the command decoder 373.

The bank address BADD may be an address for selecting one bank from among the banks BK0 and BK1. The row address RADD may be an address for selecting one of the word lines WL, and one row may correspond to a word line. The column address CADD is an address for selecting a predetermined number (e.g., eight) of the plurality of bit lines BL, and one column may correspond to the predetermined number of the bit lines BL selected by the column address CADD. The bank address BADD and the row address RADD may be provided to the row control circuit 320, and the column address CADD may be provided to the column control circuit 330.

The mode setting circuit 375 may set an internal operation corresponding to the internal address IADD according to the mode setting command MRS. For example, the mode setting circuit 375 may check a specific bit (e.g., 13-th bit) of the internal address IADD according to the mode setting command MRS, activate a repair operation signal PPR_EN when the specific bit has a logic high value, and deactivate the repair operation signal PPR_EN when the specific bit has a logic low value. The repair operation signal PPR_EN may be a signal for instructing a post-package repair operation. In addition, the mode setting circuit 375 may check another specific bit (e.g., 14-th bit) of the internal address IADD according to the mode setting command MRS, activate a mapping release signal UNDO_EN when the specific bit has a logic high level, and deactivate the mapping release signal UNDO_EN when the specific bit has a logic low level. The mapping release signal UNDO_EN may be a signal for selectively deactivating repair control signals REP_EN # generated by the repair control circuit 350. In FIG. 3, the numeral corresponding to a symbol “#” means a plurality of symbols.

The mode setting circuit 375 may check logic levels of data DQ provided from the memory controller 100 through data pads according to the repair operation signal PPR_EN and the write command WT, and may activate an individual chip signal PDA_EN for determining whether to enter an individual chip mode of a corresponding chip. For example, when the repair operation signal PPR_EN is activated, the mode setting circuit 375 may check a logic level of a data input through a first data pad, among the data DQ, after a set time from an input of the write command WT. When the data has a logic low level, the mode setting circuit 375 may activate the individual chip signal PDA_EN for a predetermined period, to indicate an entry of the individual chip mode of the corresponding chip. In the following description, the repair operation signal PPR_EN, the mapping release signal UNDO_EN, and the individual chip signal PDA_EN may be signals that are activated to a logic high level and deactivated to a logic low level.

The row control circuit 320 may be coupled to the plurality of memory cells MC of the memory cell region 310 through the plurality of word lines WL (i.e., rows). The row control circuit 320 may perform an active operation for selecting or activating at least one row selected by the row address RADD when the active command ACT is input, and perform a precharge operation for deactivating the activated row when the precharge command PCG is input.

In addition, when one of the repair control signals REP_EN # is activated during the active operation, the row control circuit 320 may map a redundancy address corresponding to the activated repair control signal, regardless of the bank address BADD and the row address RADD, to activate a redundancy row corresponding to the redundancy address. For reference, when 10 redundancy rows are arranged in the redundancy cell region 314 of each bank, the repair control signals REP_EN # are allocated as 20, i.e., the number of banks*10, and each of the 20 repair control signals may correspond to a redundancy address for designating a certain redundancy row of a specific bank. For example, a 19-th repair control signal REP_EN19 may be activated to designate a ninth redundancy row of the second bank BK1.

The column control circuit 330 may be coupled to the plurality of memory cells MC of the memory cell region 310 through the plurality of bit lines BL (i.e., columns). The column control circuit 330 may select some bit lines among the bit lines BL, by selecting a column according to the column address CADD. The column control circuit 330 may read internal data IDATA from the memory cells MC through the selected bit lines according to the read command RD. The column control circuit 330 may write internal data IDATA provided through the data input/output circuit 380 to the memory cells MC through the selected bit lines according to the write command WT.

The data input/output circuit 380 may be coupled between the column control circuit 330 and the data pads DQ, to transmit and receive the internal data IDATA to and from the memory controller 100. The data input/output circuit 380 may include a data output circuit 382 and a data input circuit 384. The data output circuit 382 may output, to the data pads DQ, the internal data IDATA read from the memory cell region 310. The data input circuit 384 may receive, through the data pads DQ, the internal data IDATA provided from the memory controller 100.

When entering the individual chip mode during the post-package repair operation, the repair control circuit 350 may store the bank address BADD and the row address RADD as one of a plurality of failure candidate addresses F_BA # and F_RA #, respectively. The repair control circuit 350 may selectively activate the plurality of repair control signals REP_EN # by comparing the bank address BADD and the row address RADD with pre-stored stored failure candidate addresses F_BA # and F_RA #, respectively. In addition, the repair control circuit 350 may deactivate the activated repair control signal according to the mapping release signal UNDO_EN. In the following embodiment, an operation in which the repair control signal is activated so that the row control circuit 320 activates the redundancy row corresponding to the activated repair control signal, may be defined as a mapping operation, and an operation in which the activated repair control signal is deactivated so that the row control circuit 320 re-activates the defective row, may be defined as a mapping release (or undo) operation or an undo operation.

In more detail, the repair control circuit 350 may include a failure address storage circuit 352 and a repair circuit 354.

The failure address storage circuit 352 may include a plurality of unit memories for storing a plurality of failure candidate addresses F_BA # and F_RA #, respectively. The unit memories may include nonvolatile memories such as an anti-fuse, an array e-fuse (ARE) circuit, a NAND flash memory, a NOR flash memory, EPROM, EEPROM, etc., or volatile memories such as DRAM or flip-flops. The failure address storage circuit 352 may receive the bank address BADD and row address RADD input together with the active command ACT when the repair operation signal PPR_EN is activated, and sequentially store the received bank address BADD and row address RADD in the unit memories when the individual chip signal PDA_EN is activated.

The repair circuit 354 may generate the plurality of repair control signals REP_EN # by comparing the bank address BADD and the row address RADD input together with the active command ACT, with the pre-stored failure candidate address F_BA # and F_RA #, respectively, and may activate a repair control signal corresponding to the failure candidate address when the comparison result matches. When mapping release signal UNDO_EN is activated, the repair circuit 354 may compare the bank address BADD and row address RADD input together with the active command ACT, with the pre-stored failure candidate address F_BA # and F_RA #, respectively, and may deactivate a repair control signal corresponding to the failure candidate address when the comparison result matches.

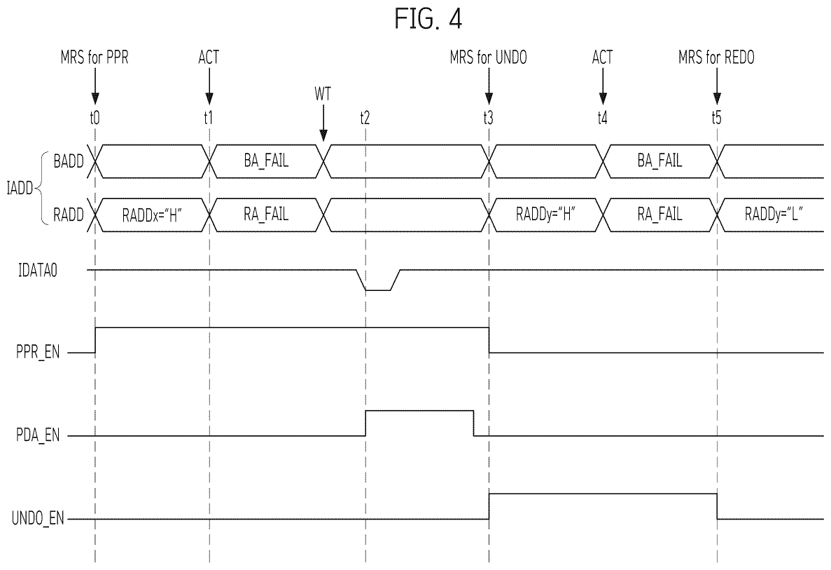

FIG. 4 is a timing diagram for describing an operation of the mode setting circuit 275 and the repair control circuit 350 of FIG. 3.

Referring to FIG. 4, at a time point t0, the mode setting circuit 275 may check a specific bit RADDx of the row address input together with the mode setting command MRS, to activate the repair operation signal PPR_EN when the specific bit RADDx is a high bit. Accordingly, the post-package repair operation starts.

At a time point t1, according to the active command ACT, the failure address storage circuit 352 may receive the bank address BA_FAIL and the row address RA_FAIL, which designate a failure address.

At a time point t2 after the write command WT is input, the mode setting circuit 275 may check the data IDATA0 input through the first data pad, among the input data DQ. When the data IDATA0 has a logic low level, the individual chip signal PDA_EN may be activated to indicate the entry of the individual chip mode of the corresponding memory chip. As the memory chip enters the individual chip mode, the failure address storage circuit 352 may store the received bank address BA_FAIL and row address RA_FAIL as one of the plurality of failure candidate addresses F_BA # and F_RA #, respectively.

The repair circuit 354 may compare the bank address BADD and the row address RADD input together with the active command ACT, with the pre-stored failure candidate address F_BA # and F_RA #, respectively, to activate a repair control signal corresponding to a failure candidate address with which the comparison result matches. The row control circuit 320 may perform a mapping operation for activating a redundancy row corresponding to the activated repair control signal.

At a time point t3, the mode setting circuit 375 may check another specific bit RADDy of the row address RADD input together with the mode setting command MRS, to activate the mapping release signal UNDO_EN when the specific bit RADDy has a logic high level. As the mapping release signal UNDO_EN is activated, the repair operation signal PPR_EN may be deactivated.

At a time point t4, the bank address BADD and the row address RADD are input together with the active command ACT after the mapping release signal UNDO_EN is activated. The repair circuit 354 may compare the bank address BADD and the row address RADD with the pre-stored failure candidate address F_BA # and F_RA #, respectively, to deactivate a repair control signal corresponding to a failure candidate address with which the comparison result matches. The row control circuit 320 may perform a mapping release operation for re-mapping the defective row, i.e., activating the defective row instead of the redundancy row.

At a time point t5, the mode setting circuit 375 may check the specific bit RADDy of the row address RADD input together with the mode setting command MRS, to deactivate the mapping release signal UNDO_EN when the specific bit RADDy has a logic low level.

Hereinafter, referring to the drawings, a method of performing a row copy operation in the memory system 10A to ensure data integrity during run-time according to an embodiment of the present disclosure will be described.

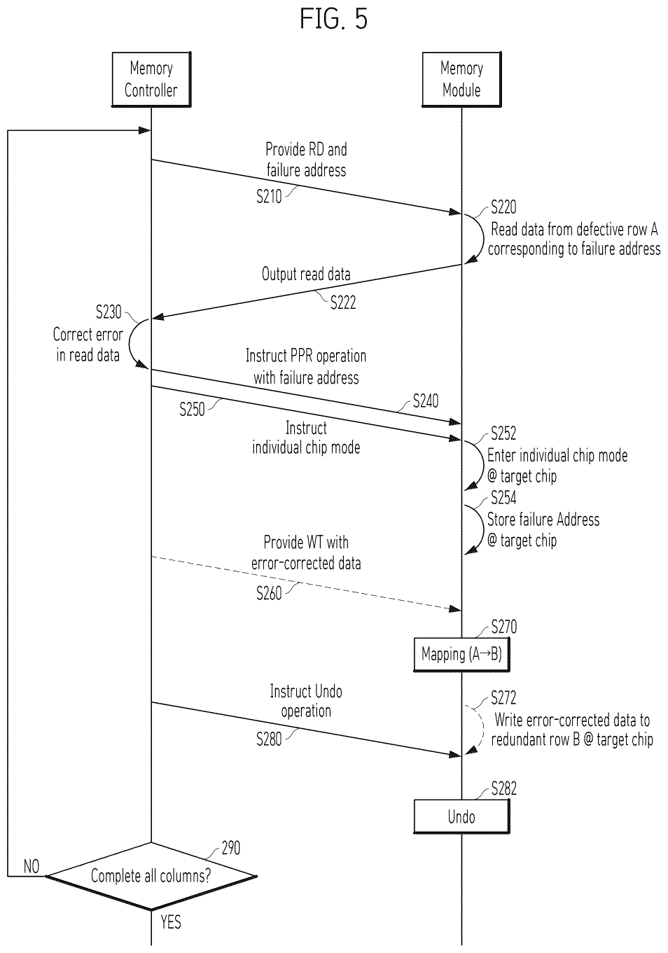

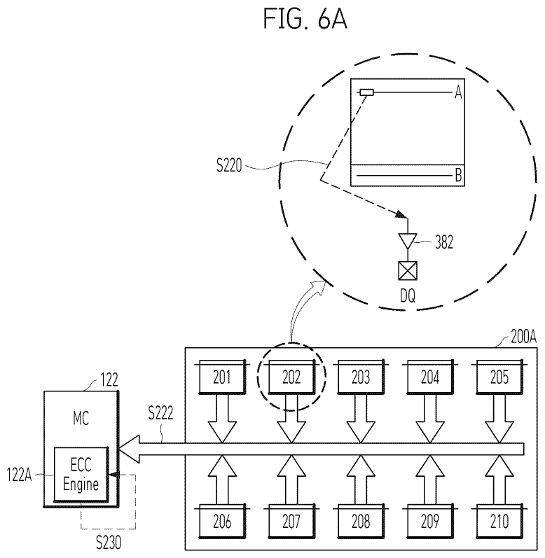

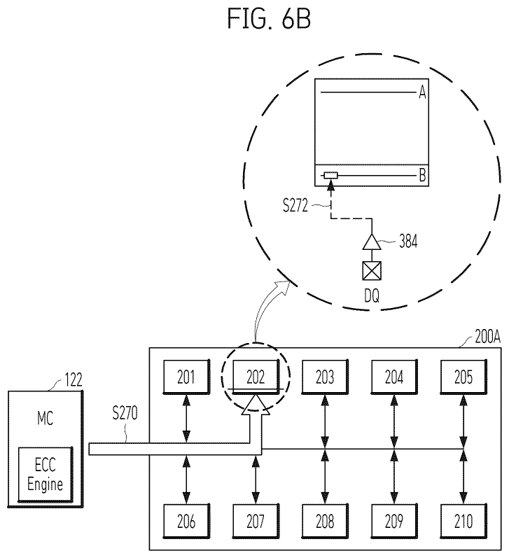

FIG. 5 is a diagram for describing an operation of the memory system 10A according to an embodiment of the present disclosure. FIGS. 6A and 6B are diagrams of operations of FIG. 5.

Referring to FIG. 5, the first module controller 122 may provide a read command RD and a failure address to the first memory module 200A (at S210). In more detail, the first module controller 122 may provide, to the first memory module 200A, an active command ACT together with the failure address including a bank address BADD and a row address RADD to indicate a location of a defective row. After a predetermined time, the first module controller 122 may provide the read command RD to the first memory module 200A together with a column address CADD. In some embodiments, the column address CADD may designate a first column among a plurality of columns.

All of the memory chips 201 to 210 of the first memory module 200A may perform a read operation of reading data from memory cells coupled to the first column and the defective row A corresponding to the failure address (at S220), and output the read data to the first module controller 122 (at S222). The first module controller 122 may correct an error in the read data from the first memory module 200A to generate error-corrected data (at S230). As shown in FIG. 6A, all of the memory chips 201 to 210 may read data from the memory cells coupled to the first column and the defective row A (at S220), and output the read data to the first module controller 122 (at S222). In this case, according to the read command RD, the data output circuit 382 of each of the memory chips 201 to 210 may output the internal data IDATA read from the memory cell region 310 to the outside through the data pads. For example, eight memory chips 201 and 208 of the 10 memory chips 201 to 210 may read 64-byte user data at once, and the remaining two memory chips 209 and 210 may read a 16-byte error correction code at once. The ECC engine 122A of the first module controller 122 may correct an error of the 64-byte user data using the 16-byte error correction code (at S230).

Thereafter, the first module controller 122 may instruct the first memory module 200A to perform a post-package repair operation and provide a failure address (at S240). In more detail, as described in FIG. 4, the first module controller 122 may set a specific bit RADDx of the row address RADD to a logic high level, and provide to the first memory module 200A the row address RADD together with a mode setting command MRS. The first memory module 200A may activate a repair operation signal PPR_EN to start a post-package repair operation (at the time point t0 of FIG. 4). After that, the first module controller 122 may provide the failure address together with the active command ACT, and the first memory module 200A may receive the failure address (at the time point t1 of FIG. 4). The memory chips 201 to 210 of the first memory module 200A may receive the failure address in common.

Thereafter, the first module controller 122 may instruct the first memory module 200A to enter an individual chip mode of a target chip (at S250). The target chip may enter the individual chip mode (at S252). As described in FIG. 4, the first module controller 122 may provide a write command WT, and, after a set time, provide data of a logic low level through a first data pad of the target chip (shown at the time point t2 of FIG. 4). The target chip of the memory chips 201 to 210 may enter the individual chip mode and store the received failure address as one of a plurality of failure candidate addresses F_BA # and F_RA # (at S254).

When there is an error in the read data during the correction at S230, the first module controller 122 may provide, to the target chip, the write command WT together with the error-corrected data (at S260). More specifically, the first module controller 122 may provide, to the first memory module 200A, the active command ACT together with the failure address. After a predetermined time, the first module controller 122 may provide the error-corrected data and the write command WT together with the column address CADD. In some embodiments, the column address CADD may designate the first column among the plurality of columns.

The target chip may compare the input failure address with the plurality of failure candidate addresses F_BA # and F_RA #, respectively, to activate a repair control signal corresponding to a failure candidate address with which the comparison result matches. Accordingly, a mapping operation for activating a redundancy row B corresponding to the activated repair control signal may be performed (at S270).

Since the mapping operation has been performed, the target chip may perform a write operation of writing the error-corrected data to the redundancy row B according to the write command WT (at S272). In this case, in the individual chip mode, only the data input circuit 384 of the target chip may receive the error-corrected data according to the write command WT. As shown in FIG. 6B, the first module controller 122 may provide the write command WT to the first memory module 200A together with 80-byte error-corrected data (at S270), and only the target chip (e.g., 202) among the 10 memory chips 201 to 210 may write the error-corrected data to the redundancy row B according to the write command WT (at S272).

When there is no error in the read data during the correction at S230, the write command WT is not provided, and the write operation may be omitted.

Thereafter, the first module controller 122 may instruct the first memory module 200A to perform a mapping release (or undo) operation (at S280). As described in FIG. 4, the first module controller 122 may set another specific bit RADDy of the row address RADD to a logic high level, and provide, to the first memory module 200A, the row address RADD together with the mode setting command MRS. The first memory module 200A may activate the mapping release signal UNDO_EN (shown at the time point t3 of FIG. 4).

When the above operations are not performed for all columns (“NO” in S290), the first module controller 122 may change a value of the column address CADD to designate a second column and provide a read command RD and a failure address to the first memory module 200A again (at S210). The first module controller 122 may provide, to the first memory module 200A, an active command ACT together with the failure address (shown at the time point t4 of FIG. 4). After a predetermined time, the first module controller 122 may provide, to the first memory module 200A, the read command RD together with the column address CADD designating the second column. In this case, since the mapping release signal UNDO_EN is activated, the repair control signal corresponding to the failure candidate address matching the failure address may not be activated, to thereby perform a mapping release operation. Accordingly, the 10 memory chips 201 to 210 of the first memory module 200A may perform a read operation of reading data from the second column of the defective row A corresponding to the failure address (at S220), and output the read data to the first module controller 122 (at S222). The above operations S210 to S290 may be repeatedly performed on all columns.

As described above, the memory system according to an embodiment of the present disclosure may perform a row copy operation by repeatedly performing, to all columns of a defective row, reading data from the defective row of all chips by a mapping release operation, correcting an error in the read data, and writing error-corrected data only to a redundancy row of a target chip by a mapping operation.

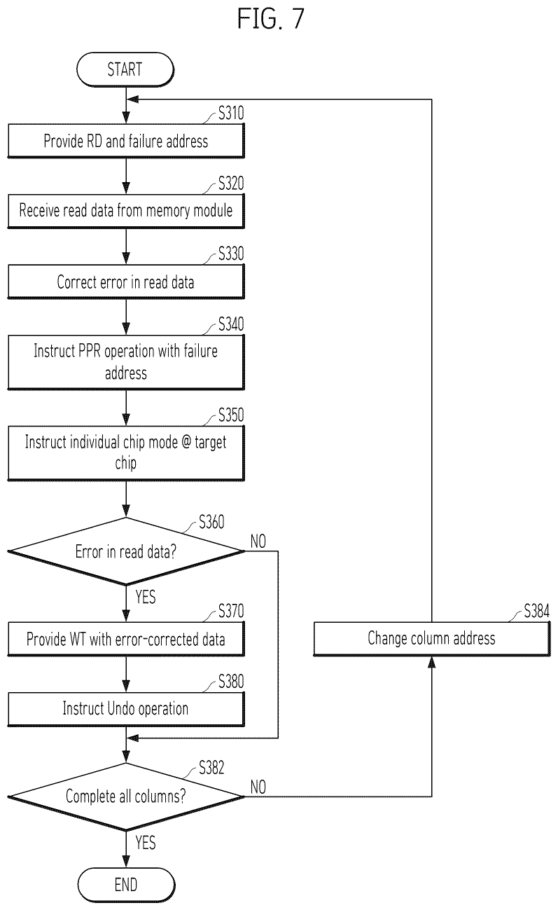

FIG. 7 is a flowchart describing an operation of the memory controller 100 according to an embodiment of the present disclosure.

Referring to FIG. 7, the first module controller 122 of the memory controller 100 may provide a read command RD and a failure address to the first memory module 200A of the memory device 200 (at S310). In more detail, the first module controller 122 may provide, to the first memory module 200A, an active command ACT together with the failure address including a bank address BADD and a row address RADD to indicate a location of a defective row. After a predetermined time, the first module controller 122 may provide, to the first memory module 200A, the read command RD together with a column address CADD. In this case, the column address CADD may designate a first column among a plurality of columns. For reference, when a read operation for the first column is instructed, the first module controller 122 may instruct a mapping release operation by setting another specific bit RADDy of the row address RADD to a logic low level, and by providing the row address RADD together with a mode setting command MRS, prior to the active command ACT.

The first module controller 122 may receive data read from the first memory module 200A (at S320), and correct an error in the read data to generate error-corrected data (at S330).

The first module controller 122 may instruct the first memory module 200A to perform a post-package repair PPR operation, and provide a failure address (at S340). The first module controller 122 may instruct the post-package repair operation by setting a specific bit RADDx of the row address RADD to a logic high level, and by providing the row address RADD together with the mode setting command MRS to the first memory module 200A. Further, the first module controller 122 may provide, to the first memory module 200A, the failure address together with the active command ACT.

The first module controller 122 may instruct the first memory module 200A to enter an individual chip mode of a target chip (at S350). The first module controller 122 may instruct an entry of the target chip to the individual chip mode, by providing a write command WT, and, after a set time, providing data of a logic low level through a first data pad of the target chip.

When it is determined that there is an error in the data read during the correction at S330 (“YES” in S360), the first module controller 122 may provide, to the target chip, the write command WT together with the error-corrected data (at S370). More specifically, the first module controller 122 may provide, to the first memory module 200A, the active command ACT together with the failure address. After a predetermined time, the first module controller 122 may provide, to the first memory module 200A, the error-corrected data and the write command WT together with the column address CADD. In some embodiments, the column address CADD may designate the first column among the plurality of columns. At the time when the write operation is completed, the first module controller 122 may instruct the first memory module 200A to perform a mapping release operation (i.e., undo operation) by setting another specific bit RADDy of the row address RADD to a logic high level, and by providing the row address RADD together with the mode setting command MRS (at S380).

When it is determined that there is no error in the read data during the correction at S330 (“NO” in S360), the first module controller 122 does not provide the write command WT, and the write operation of the first memory module 200A may be omitted.

When it is determined that the above operations S310 to S380 are not performed on all columns (“NO” in S382), the first module controller 122 may designate a next column by changing a value of the column address CADD (at S384). For example, the first module controller 122 may increase a value of the column address CADD by “+1” to generate the column address CADD to designate a second column.

The first module controller 122 may terminate the process when the above operations S310 to S380 are performed on all columns (“YES” in S382).

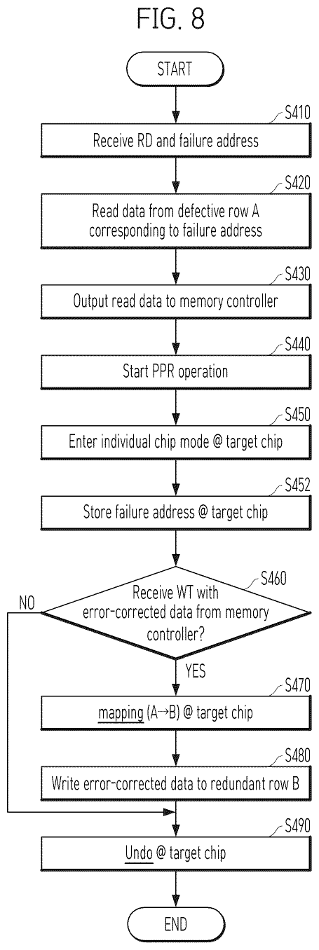

FIG. 8 is a flowchart describing an operation of the memory device 200 according to an embodiment of the present disclosure.

Referring to FIG. 8, the first memory module 200A of the memory device 200 may receive a read command RD and a failure address from the first module controller 122 of the memory controller 100 (at S410). In more detail, the first memory module 200A may receive an active command ACT together with the failure address including a bank address BADD and a row address RADD to indicate a location of a defective row. After a predetermined time, the first memory module 200A may receive the read command RD together with the column address CADD. In some embodiments, the column address CADD may designate a first column among a plurality of columns.

All of the memory chips 201 to 210 of the first memory module 200A may perform a read operation of reading data from memory cells coupled to the first column and the defective row A corresponding to the failure address (at S420), and output the read data to the first module controller 122 (at S430).

Then, the first memory module 200A may start a post-package repair PPR operation when receiving an instruction from the first module controller 122 (at S440). The first memory module 200A may check a specific bit RADDx of the row address RADD input together with a mode setting command MRS, to activate a repair operation signal PPR_EN. The memory chips 201 to 210 of the first memory module 200A may receive the failure address according to the active command ACT.

Thereafter, a target chip of the first memory module 200A may enter an individual chip mode when receiving an instruction from the first module controller 122 (at S450). The target chip may enter the individual chip mode by checking a logic level of a data input through a first data pad, among data DQ, and, after a set time from an input of a write command WT, activating an individual chip signal PDA_EN when the data has a logic low level. The target chip may store the failure address as one of a plurality of failure candidate addresses F_BA # and F_RA # (at S452).

Thereafter, the target chip may selectively receive the write command WT together with error-corrected data (at S460). The target chip may receive the active command ACT together with the failure address, and after a predetermined time, receive the write command WT together with the error-corrected data and the column address CADD. In some embodiments, the column address CADD may designate the first column among the plurality of columns.

When it is determined that the write command WT is input together with the error-corrected data (“YES” of S460), the target chip may compare the failure address with the plurality of failure candidate addresses F_BA # and F_RA #, respectively, to activate a repair control signal corresponding to a failure candidate address with which the comparison result matches. Accordingly, a mapping operation for activating a redundancy row B corresponding to the activated repair control signal may be performed (at S470). Since the mapping operation has been performed, the target chip may perform a write operation for writing the error-corrected data to the redundancy row B according to the write command WT (at S480).

When it is determined that the write command WT is not input (“NO” in S460), the write operation may be omitted.

Thereafter, the first memory module 200A may perform a mapping release operation when receiving an instruction from the first module controller 122 (at S490). The first memory module 200A may check another specific bit RADDy of the row address RADD, input together with the mode setting command MRS, to activate a mapping release signal UNDO_EN.

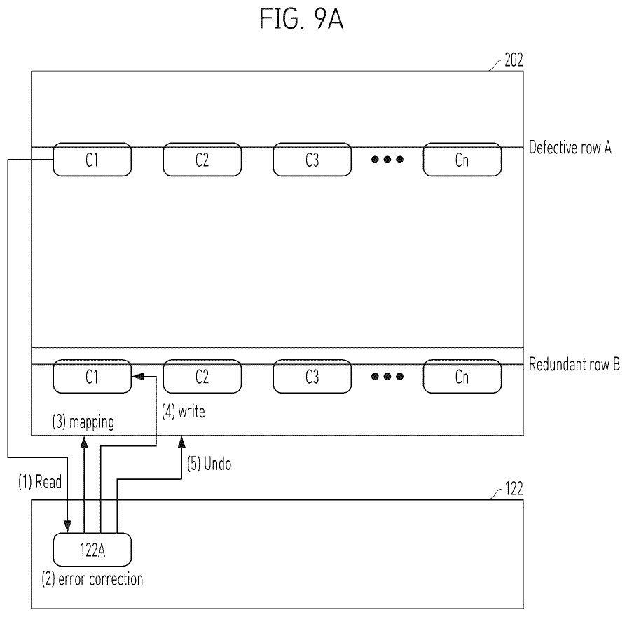

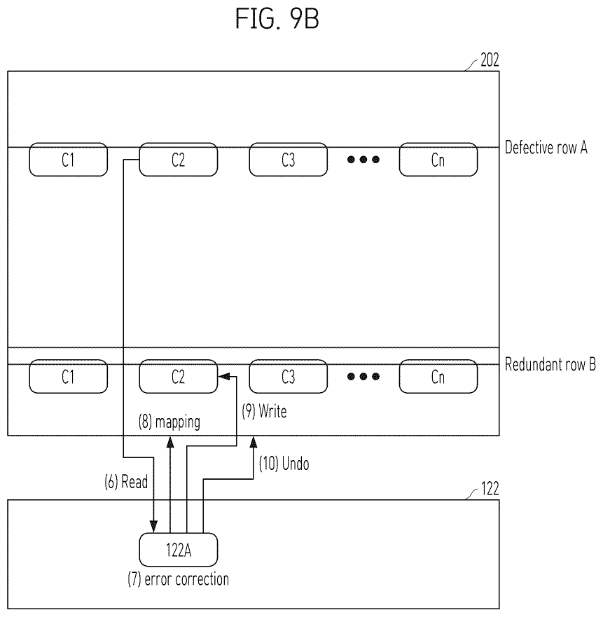

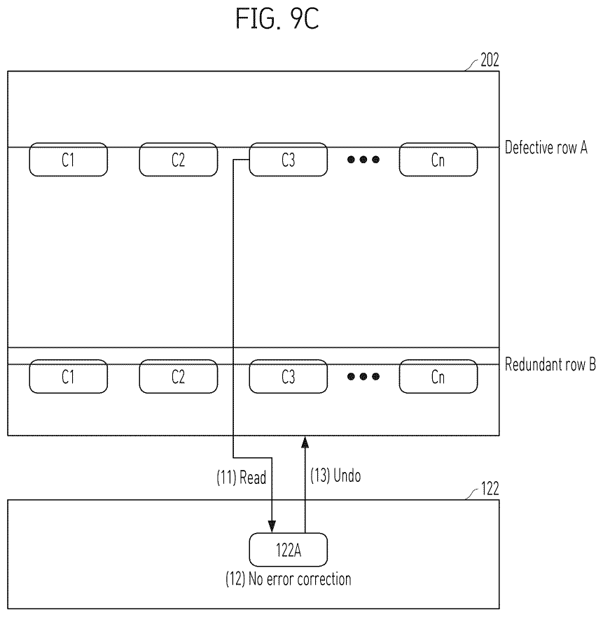

FIGS. 9A to 9C are diagrams for describing a row copy operation of a memory system according to an embodiment of the present disclosure. In FIGS. 9A to 9C, the first module controller 122 and only a target chip (e.g., 202) of the memory chips 201 to 210 of the first memory module 200A are illustrated.

Referring to FIG. 9A, the memory chips 201 to 210 of the first memory module 200A may perform a read operation (1) of reading data from a first column C1 of a defective row A. The ECC engine 122A of the first module controller 122 may perform an error correction operation (2) of correcting an error in the read data from the first memory module 200A. As an error is detected in the read data, the target chip 202 of the memory chips 201 to 210 may perform a mapping operation (3) of mapping the defective row A to a redundancy row B, and then perform a write operation (4) of writing error-corrected data to the first column C1 of the redundancy row B. Thereafter, the target chip 202 may perform a mapping release (undo) operation (5) of re-mapping the redundancy row B to the defective row A.

Referring to FIG. 9B, a read operation (6) for reading data from a second column C2 of the defective row A and an error correction operation (7) for correcting an error in the read data may be sequentially performed. When an error is detected in the read data, a mapping operation (8) for mapping the defective row A to a redundancy row B, and a write operation (9) for writing error-corrected data to the second column C2 of the redundancy row B may be sequentially performed. Thereafter, a mapping release (undo) operation (10) for re-mapping the redundancy row B to the defective row A may be performed again.

Referring to FIG. 9C, a read operation (11) for reading data of a third column C3 of the defective row A and an error correction operation (12) for correcting an error in the read data may be sequentially performed. When it is determined that no error is detected in the read data, the mapping operation (3) or (8) and the write operation (4) or (9) described in FIGS. 9A and 9B may be omitted. Thereafter, a mapping release (undo) operation (13) for selecting the defective row A again may be performed.

The above process may be repeatedly performed on all columns C1 to Cn of the defective row A.

As described above, among the columns C1 to Cn of the defective row A, an operation of re-writing error-corrected data may be omitted for columns in which no error is detected, thereby reducing unnecessary power consumption and optimizing the time required for the row copy operation.

In the above embodiment, a row copy operation performed during row repair related to a bank address and a row address is described as an example, but the embodiments of the present disclosure are not limited thereto. The technical concept of the present disclosure may also be applied to a copy operation performed during column repair.

Various embodiments of the present disclosure have been described in the drawings and specification. Although specific terminologies are used here, the terminologies are only to describe the embodiments of the present disclosure. Therefore, the embodiments of the present disclosure are not restricted to the above-described embodiments and many variations are possible within the spirit and scope of the present disclosure. It should be apparent to those skilled in the art that various modifications can be made based on the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the disclosure and the following claims.

For example, for the logic gates and transistors provided as examples in the above-described embodiments, different positions and types may be implemented depending on the polarity of the input signal.

What is claimed is:

1. An operating method of a memory system, the operating method comprising:
reading, by a plurality of memory chips, data from a first column of a defective row corresponding to a failure address;
generating, by a memory controller, error-corrected data by correcting an error of the read data; and
mapping, by a target chip selected from the plurality of memory chips, the failure address to a redundancy address, and writing the error-corrected data to a first column of a redundancy row corresponding to the redundancy address,
wherein the reading, the generating, the mapping, and the writing are repeatedly performed on remaining columns of the defective row.

2. The operating method of claim 1, further comprising:
providing, by the memory controller, a command to instruct a post-package repair operation and the failure address;
controlling, by the memory controller, the target chip to enter an individual chip mode; and
storing, by the target chip, the failure address as one of a plurality of failure candidate addresses.

3. The operating method of claim 1, wherein mapping the failure address includes:
mapping the failure address to the redundancy address according to a result of comparing a plurality of pre-stored failure candidate addresses with the failure address, respectively.

4. The operating method of claim 1, further comprising: controlling, by the memory controller, the target chip to omit writing the error-corrected data when there is no error in the read data.

5. A memory system comprising:
a plurality of memory chips configured to read data from a defective row corresponding to a failure address; and
a memory controller configured to receive the read data from the plurality of memory chips, and generate error-corrected data by correcting an error in the read data,
wherein a target chip selected from the plurality of memory chips performs mapping the failure address to a redundancy address, writing the error-corrected data to a redundancy row corresponding to the redundancy address, and releasing the mapping.

6. The memory system of claim 5,
wherein the memory controller provides, to the plurality of memory chips, a command to instruct a post-package repair operation and the failure address, and controls the target chip to enter an individual chip mode, and
wherein the target chip stores the failure address as one of a plurality of failure candidate addresses and maps the failure address to the redundancy address according to a result of comparing the plurality of failure candidate addresses with the failure address, respectively.

7. The memory system of claim 5, wherein the memory controller controls the target chip to omit writing the error-corrected data when there is no error in the read data.

8. The memory system of claim 5, wherein the memory controller communicates with a host using a compute express link (CXL) type interface.

9. An operating method of a memory controller, the operating method comprising:
providing, to a plurality of memory chips, a read command with a failure address indicating a defective row;
generating error-corrected data by correcting an error in data read from the plurality of memory chips;
controlling a target chip selected from the plurality of memory chips, to enter an individual chip mode; and
instructing, to the target chip, a mapping operation for mapping the defective row of the target chip to a redundancy row, and providing a write command with the error-corrected data,
wherein the providing, the generating, the entering, and the instructing of the mapping operation are repeatedly performed on columns of the defective row.

10. The operating method of claim 9, wherein controlling the target chip includes:
providing, to the target chip, a command to instruct a post-package repair operation and the failure address; and
controlling the target chip to enter the individual chip mode so that the target chip stores the failure address as one of a plurality of failure candidate addresses,
wherein the mapping operation is performed according to a result of comparing a plurality of pre-stored failure candidate addresses with the failure address, respectively.

11. The operating method of claim 9, further comprising:
controlling the target chip to omit writing the error-corrected data when there is no error in the read data.

12. The operating method of claim 9, further comprising:
communicating with a host using a compute express link (CXL) type interface.

13. A memory device comprising:
a memory cell region including a plurality of normal rows and a plurality of redundancy rows;
a repair control circuit configured to selectively activate a plurality of repair control signals according to a result of comparing an input address with a plurality of failure candidate addresses, and deactivate an activated repair control signal of the plurality of repair control signals according to a mapping release signal;
a row control circuit configured to select a row corresponding to the input address or a redundancy address, from the memory cell region, according to the activated repair control signal; and
a data input and output (input/output) circuit configured to provide, to a memory controller, first data read from the memory cell region, and second data provided from the memory controller to the memory cell region when entering an individual chip mode.

14. The memory device of claim 13, wherein the second data is error-corrected data of the first data.

15. The memory device of claim 13, wherein the repair control circuit stores the input address as one of the plurality of failure candidate addresses in the individual chip mode during a post-package repair operation.

16. The memory device of claim 13, wherein the repair control circuit includes:
a failure address storage circuit configured to store the input address as one of the plurality of failure candidate addresses, in the individual chip mode during a post-package repair operation; and
a repair circuit configured to selectively activate the plurality of repair control signals according to the result of comparing the input address with the plurality of candidate addresses, respectively, and deactivate an activated repair control signal of the plurality of repair control signals according to the mapping release signal.

17. The memory device of claim 13, further comprising:
a mode setting circuit configured to generate a repair operation signal indicating a post-package repair operation, or the mapping release signal, by checking some bits of the input address according to a mode setting command, and determine entry into the individual chip mode by checking a logic level of a data input after a set time from an input of a write command according to the repair operation signal.

18. The memory device of claim 13, wherein the row control circuit selects, as the selected row, one of the plurality of normal rows, which corresponds to the input address, and selects one of the plurality of redundancy rows, which corresponds to the redundancy address, according to the activated repair control signal.

19. The method of claim 1, further comprising: releasing, by the target chip, the mapping in response to instruction for a mapping release operation from the memory controller.

20. The operating method of claim 9, further comprising:
instructing, to the target chip, a mapping release operation of re-mapping the redundancy row of the target chip to the defective row.
